(19) United States
(12) Patent Application Publication
(10) Pub. No.: US 2025/0006554 A1
(43) Pub. Date: Jan. 2, 2025

(54) REDUCED TUNGSTEN GALVANIC CORROSION IN WET CLEANING FOR ADVANCED SEMICONDUCTOR METALLIZATION FEATURES

(71) Applicant: Intel Corporation, Santa Clara, CA (US)

(72) Inventors: Ramanan Ehamparam, Beaverton, OR (US); Ebubekir Dogan, Portland, OR (US); Maria Stancescu, Lake Oswego, OR (US)

(73) Assignee: Intel Corporation, Santa Clara, CA (US)

(21) Appl. No.: 18/215,692

(22) Filed: Jun. 28, 2023

(51) Int. Cl. H01L 21/768; H01L 21/67

(52) U.S. Cl. CPC H01L 21/76876; H01L 21/67069; H01L 21/67075; H01L 21/76856

(57) ABSTRACT

Devices, systems, and techniques are described herein related to reducing or eliminating galvanic corrosion of tungsten conductive features within tungsten-boron liners during wet clean thereof. The tungsten-boron liner is treated with a hydrogen/nitrogen plasma to modify a portion of the liner extending from the top surface to include tungsten, boron, nitrogen, and optionally oxygen. The modified portion of the liner reduces or eliminates galvanic corrosion during wet etch clean.

### BACKGROUND

Higher performance, lower cost, increased miniaturization, and greater density of integrated circuits (ICs) are ongoing goals of the electronics industry. In the context of transistor devices, tungsten (W) is widely used as a via, trench, or other metallization material. For example, tungsten may be used as a contact metal for source and drain contact, as a gate electrode metal, as a via metal, as a trench metal, or in other metallization contexts. In some process flows, plasma dry etch is used to expose a tungsten metal feature. This plasma dry etch leaves polymer/residue that is subsequently removed by a wet clean operation (e.g., a wet etch). During this wet clean, tungsten can suffer from galvanic corrosion. The galvanic corrosion leads to open chains, yield impacts, and other concerns. For example, the galvanic corrosion may be damage induced by the difference between the bulk tungsten and the liner material on which bulk tungsten is formed as those dissimilar materials are coupled to a corrosive electrolyte in the wet etch clean.

It is with respect to these problems that the current improvements are needed. The techniques and structures discussed herein offer improved metallization features for the continued advancement of ICs in a wide variety of applications. Such improvements may become critical as the desire to deploy advanced IC devices becomes even more widespread.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 is a flow diagram illustrating methods for reducing or eliminating galvanic corrosion in tungsten conductive features within tungsten-boron based meta liners;

FIGS. 2, 3, 4, 5, 6, 7, 8, 9, 10, and 11 are cross-sectional views of integrated circuit structure evolving as methods are practiced to form a tungsten conductive feature within a tungsten-boron based liner having a modified top surface portion;

FIG. 12 illustrates exemplary systems employing integrated circuit structures having a tungsten conductive feature in a corrosion resistant liner; and

FIG. 13 is a functional block diagram of an electronic computing device, all in accordance with some embodiments.

### DETAILED DESCRIPTION

One or more embodiments or implementations are now described with reference to the enclosed figures. While specific configurations and arrangements are discussed, it should be understood that this is done for illustrative purposes only. Persons skilled in the relevant art will recognize that other configurations and arrangements may be employed without departing from the spirit and scope of the description. It will be apparent to those skilled in the relevant art that techniques and/or arrangements described herein may also be employed in a variety of other systems and applications other than what is described herein.

Reference is made in the following detailed description to the accompanying drawings, which form a part hereof, wherein like numerals may designate like parts throughout to indicate corresponding or analogous elements. It will be appreciated that for simplicity and/or clarity of illustration, elements illustrated in the figures have not necessarily been drawn to scale. For example, the dimensions of some of the elements may be exaggerated relative to other elements for clarity. Further, it is to be understood that other embodiments may be utilized, and structural and/or logical changes may be made without departing from the scope of claimed subject matter. It should also be noted that directions and references, for example, up, down, top, bottom, over, under, and so on, may be used to facilitate the discussion of the drawings and embodiments and are not intended to restrict the application of claimed subject matter. Therefore, the following detailed description is not to be taken in a limiting sense and the scope of claimed subject matter defined by the appended claims and their equivalents.

In the following description, numerous details are set forth. However, it will be apparent to one skilled in the art, that the present invention may be practiced without these specific details. In some instances, well-known methods and devices are shown in block diagram form, rather than in detail, to avoid obscuring the present invention. Reference throughout this specification to “an embodiment” or “one embodiment” means that a particular feature, structure, function, or characteristic described in connection with the embodiment is included in at least one embodiment of the invention. Thus, the appearances of the phrase “in an embodiment” or “in one embodiment” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. Herein, the term “predominantly” indicates not less than 50% of a particular material or component while the term “substantially pure” indicates not less than 95% of the particular material or component and the term “pure” indicates not less than 99% of the particular material or component. Unless otherwise indicated, such material percentages are based on atomic percentage. Herein the term concentration is used interchangeably with material percentage and also indicates atomic percentage unless otherwise indicated.

The terms “coupled” and “connected,” along with their derivatives, may be used herein to describe structural relationships between components. It should be understood that these terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship, an electrical relationship, a functional relationship, etc.).

The terms “over,” “under,” “between,” “on”, and/or the like, as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features. The term immediately adjacent indicates such features are in direct contact. Furthermore, the terms “substantially,” “close,” “approximately,” “near,” and “about,” generally refer to being within +/−10% of a target value. The term layer as used herein may include a single material or multiple materials. As used in throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C. The terms “lateral”, “laterally adjacent” and similar terms indicate two or more components are aligned along a plane orthogonal to a vertical direction of an overall structure. As used herein, the terms “monolithic”, “monolithically integrated”, and similar terms indicate the components of the monolithic overall structure form an indivisible whole not reasonably capable of being separated.

Devices, conductive features, integrated circuit dies, apparatuses, systems, and techniques are described herein related to reducing tungsten galvanic corrosion during wet etch clean by application of a hydrogen/nitrogen plasma treatment to the top surface of a nucleation liner of a tungsten conductive feature.

As discussed, tungsten is widely used in the electronics industry as the selected metal for conductive features in a wide variety of applications. As used herein, the term conductive feature indicates a conductor or metal structure of an integrated circuit (IC) device. The conductive feature may be a source or drain contact, a gate electrode or a portion of a gate electrode, a metal via, a trench metal, a metal line, or others. The conductive feature may be within a liner (or nucleation layer), which may also provide a conductor or conductive structure of the IC device. For example, both the conductive feature and the liner may be conductive and may provide ohmic contact to other components or features of the IC device. In some embodiments, the liner is a nucleation layer for deposition of the bulk metal of the conductive feature, and the liner may be characterized as a nucleation layer, a metal liner, or the like.

Currently, tungsten suffers from galvanic corrosion during wet clean steps (e.g., a wet etch) that is performed after plasma dry etch to remove polymer/residue that is present after the plasma dry etch. For example, a liner or nucleation layer may be formed using a boron/hydrogen (B₂H₆) reaction with tungsten hexafluoride (WF₆). The B₂H₆ based nucleation layer, which includes boron, is used to grow the bulk tungsten fill of the conductive feature. After the conductive feature is buried by insulative material, a dry plasma etch is used to pattern the insulative material to expose the conductive features for higher level metallization, for example. A post plasma wet etch is then used after the plasma etch to remove undesirable polymer/residue left by the plasma etch. That is, to make clean contact to the exposed tungsten conductor by higher level metallizations, the polymer/residue is removed by wet etch clean using, for example, alkanolamine chemistries. During the wet etch processing, galvanic corrosion of the bulk tungsten and the tungsten-based liner (e.g., tungsten with small amounts of boron) can occur, which corrodes the bulk tungsten or liner or both. For example, the alkanolamine chemistries have a basic pH, which enhances tungsten corrosion due to its favorable electrochemical potential. This corrosion, in turn, leads to poor contact, high resistivity, open chains, yield impacts, and other problems. This difficulty becomes even more pronounced as the conductive features are scaled to smaller and smaller sizes. Currently, galvanic corrosion may be mitigated by adding corrosion inhibitors to the wet polymer cleaning formulation. However, the corrosion inhibitors have a variety of drawbacks including increasing manufacturing costs, posing a threat to the environment, introducing particle defects that negatively impact yield, and being incompatible with some process flows.

Herein, an approach to prevent galvanic corrosion of B₂H₆ based nucleation tungsten liners or layers during wet clean (e.g., using basic pH chemistries) with no added tungsten corrosion inhibitors is presented. The discussed techniques include surface modification of the B₂H₆ based nucleation tungsten liner or layer by a hydrogen/nitrogen (H₂/N₂) plasma treatment step before the wet etch clean. Notably, the wet etch clean may use the same wet alkanolamine chemistries containing standard polymer/residue cleaning wet chemistry.

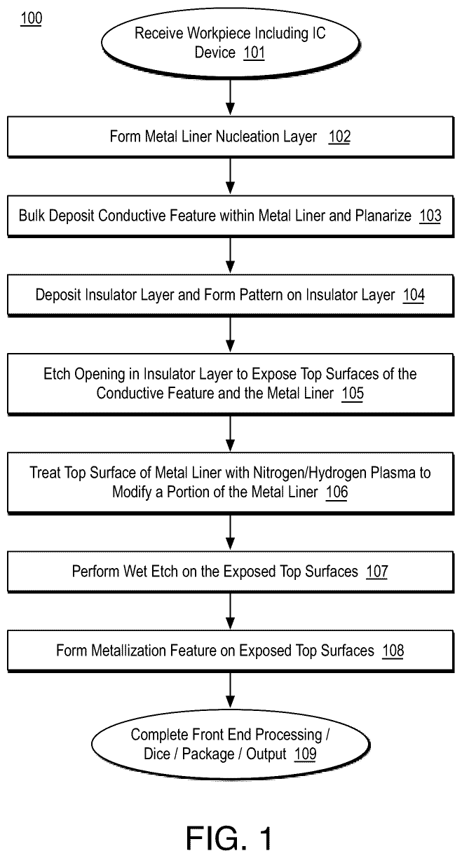

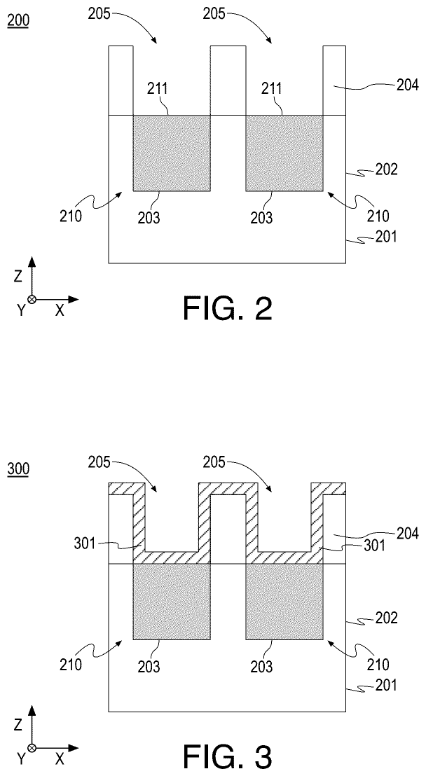

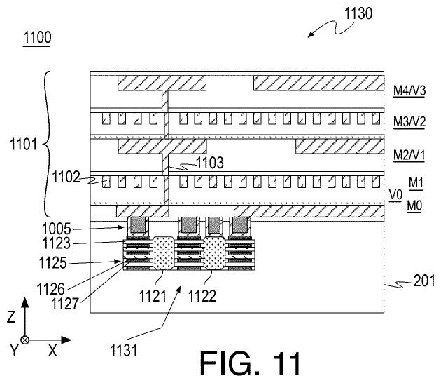

FIG. 1 is a flow diagram illustrating methods 100 for reducing or eliminating galvanic corrosion in tungsten conductive features within tungsten-boron based meta liners, arranged in accordance with at least some implementations of the present disclosure. FIGS. 2, 3, 4, 5, 6, 7, 8, 9, 10, and 11 are cross-sectional views of integrated circuit structure evolving as methods 100 are practiced to form a tungsten conductive feature within a tungsten-boron based liner having a modified top surface portion, arranged in accordance with some embodiments of the disclosure. FIG. 11 is a cross-section view of the conductive feature within a tungsten-boron based liner deployed in the context of transistor gate or source/drain contacts. However, the conductive feature within a tungsten-boron based liner may be used in any suitable integrated circuit device context.

Methods 100 begin at input operation 101, where a workpiece including at least a partially integrated circuit device is received for processing. For example, a substrate may be received for processing such that an integrated circuit (IC) device such as a transistor or transistor structure has been at least partially fabricated over the substrate. As used herein, the term IC device indicates any device that may be deployed in an IC inclusive of transistors, resistors, capacitors, diodes, metallization vias, metallization lines, and so on. The IC device may be deployed in a device layer, for example, and the conductive features discussed herein may contact a component of the IC device or may contact a metallization feature that is already in contact with the IC device. Notably, the conductive features discussed herein and corresponding liners may be deployed in a wide variety of contexts in the fabrication of an IC.

FIG. 2 illustrates a cross-sectional side view of an integrated circuit structure 200 including one or more components 203 of IC devices 210 that are to be contacted by a conductive feature, formed over a substrate 201. For example, components 203 may be source or drain structures, gate components, or channel semiconductor materials of a transistor, electrodes of a resistor, capacitor, diode, or other component, or a conductive feature such as a metal line or via. Similarly, IC devices 210 may be any suitable devices such as transistors (planar transistors, multi-gate transistors, nanowire or nanoribbon transistors, etc.) resistors, capacitors, diodes, or other IC devices. For example, a conductive feature is to electrically couple to each of components 203 for the fabrication of an IC or IC system.

Substrate 201 may include any suitable material or materials. For example, substrate 201 may be a substrate substantially aligned along a predetermined crystal orientation (e.g., <100>, <111>, <110>, or the like). In some embodiments, substrate 201 is a semiconductor material such as monocrystalline silicon (Si), germanium (Ge), silicon germanium (SiGe), III-V materials (e.g., gallium arsenide (GaAs)), a silicon carbide (SiC), a sapphire (Al₂O₃), or any combination thereof. In some embodiments, substrate 201 is silicon having a <111> crystal orientation. Components 203 may be any suitable materials based on the device being deployed. As shown, components 203 may be embedded within an insulator material 202, which is illustrated as continuous with substrate 201 for the sake of clarity of presentation.

Furthermore, a patterned insulator material 204 may expose, via openings 205, at least top surfaces 211 of components 203 for contacting by a tungsten conductive feature as discussed herein below. Patterned insulator material 204 may be formed and patterned using any suitable technique or techniques. For example, a bulk insulator material layer may be provided over IC devices 210. The bulk insulator material layer may then be patterned and etched using lithography and dry etch techniques, for example. Insulator material 202 and patterned insulator material 204 may be any suitable material or materials such as one or more of silicon oxide, silicon nitride, silicon oxynitride, silicon carbide, and so on. In addition to top surfaces 211 of components 203 being exposed, other surfaces such as sidewall surfaces of components 203 may also be exposed for contact in some embodiments.

Returning to FIG. 1, processing continues at operation 102, where a tungsten-boron based liner or nucleation layer is formed on a component of an IC device to be contacted by a conductive feature. The liner or nucleation layer may be formed using any suitable technique or techniques. In some embodiments, the liner or nucleation layer formed by deposition using a boron/hydrogen (B₂H₆) reaction with tungsten hexafluoride (WF₆). The liner or nucleation layer provides a thin (e.g., 10 nm or less) layer of a tungsten boron film for the subsequent growth of pristine tungsten. In some embodiments, the deposited liner or nucleation layer is greater than 97% tungsten and not more than 3% boron. In some embodiments, the deposited liner or nucleation layer is greater than 96% tungsten and not more than 4% boron. In some embodiments, the deposited liner or nucleation layer is greater than 95% tungsten and not more than 5% boron. In some embodiments, the deposited liner or nucleation layer is greater than 95% tungsten and not more than 3% boron. For example, the deposited liner or nucleation layer may be 2-5% boron and the balance tungsten. The liner or nucleation layer may have any suitable thickness such as a thickness in the range of 1 to 5 nm. In some embodiments, the liner or nucleation layer has a thickness of not more than 10 nm. In some embodiments, the liner or nucleation layer has a thickness of not more than 5 nm. In some embodiments, the liner or nucleation layer has a thickness of not more than 2 nm.

FIG. 3 illustrates a cross-sectional side view of an integrated circuit structure 300 similar to integrated circuit structure 200 after the formation of a liner 301 as discussed with respect to operation 102. As shown, liner 301 may be conformal to exposed surfaces of components 203 and insulator material 204. Notably, liner 301 provides high performance electrical contact to components 203. As discussed, liner 301 is substantially pure tungsten having a tungsten atomic percentage of more than 95% tungsten. In some embodiments, liner 301 is not less than 97% tungsten. In some embodiments, liner 301 is not less than 98% tungsten. Liner 301 further includes low amounts of boron such as not more than 3% boron, not more than 2% boron, or not more than 1% boron. In some embodiments, liner 301 has an atomic percentage of boron in the range of 1 to 5%. In some embodiments, liner 301 has an atomic percentage of boron in the range of 2 to 4%. In some embodiments, liner 301 has an atomic percentage of boron in the range of 1.5 to 3%. As discussed, liner 301 may be formed via nucleation layer deposition using a boron/hydrogen (B₂H₆) reaction with tungsten hexafluoride (WF₆).

Returning to FIG. 1, processing continues at operation 103, where a pure tungsten conductive feature is formed within the liner formed at operation 102 by providing a tungsten fill operation followed by planarization. The tungsten fill operation may be performed using any suitable technique or techniques such as chemical vapor deposition (CVD). The tungsten fill may pristine or pure tungsten having an atomic percentage of not less than 99% tungsten. In some embodiments, the tungsten fill is not less than 99.5% tungsten. In some embodiments, tungsten fill is not less than 99.9% tungsten. In some embodiments, tungsten fill is not less than 95% tungsten. The planarization operation may also be performed using any suitable technique or techniques such as chemical mechanical polishing operations. Notably, the planarization operation provides for a desired conductive feature while exposing a portion of the liner fabricated at operation 102. For example, the conductive feature and the liner may have an exposed top surface.

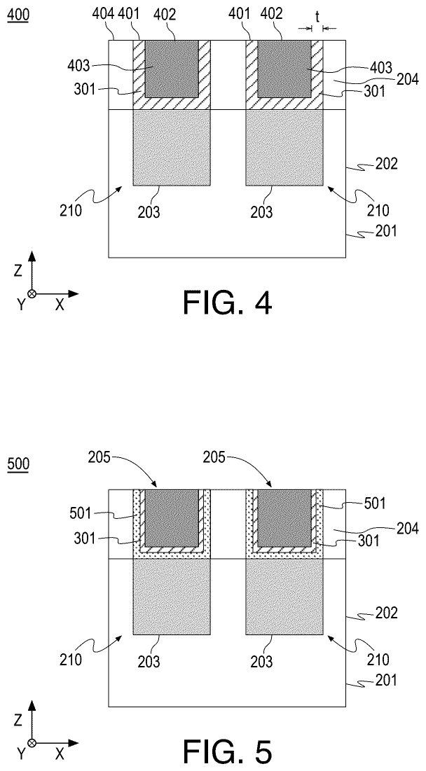

FIG. 4 illustrates a cross-sectional side view of an integrated circuit structure 400 similar to integrated circuit structure 300 after the formation of conductive features 403 including planarization to form top surfaces 401 of liners 301 and top surfaces 402 of conductive features 403 as discussed with respect to operation 103. As shown, conductive feature 403 is within liner 301 with top surface 402 of conductive feature 403 and top surface 401 of liner 301 being substantially coplanar in the x-y plane. Furthermore, a top surface 404 of insulator material 204 is substantially coplanar with top surfaces 401, 402 in the x-y plane. As discussed, conductive feature 403 is substantially pure tungsten or pure tungsten. In some embodiments, conductive feature 403 is not less than 95% tungsten. In some embodiments, conductive feature 403 is not less than 99% tungsten. In some embodiments, conductive feature 403 is not less than 99.5% tungsten. In some embodiments, conductive feature 403 is not less than 99.9% tungsten. Notably, the difference in materials between conductive feature 403 and liner 301 makes them susceptible to corrosion during subsequent wet etch processing as discussed further herein below. As discussed, conductive feature 403 may be formed using bulk tungsten deposition techniques such as CVD.

As shown, liner 301 has a lateral width or thickness t at top surface 401 such that the lateral width is in the x-y plane. The lateral width or thickness t may be any thickness discussed with respect to the formation of liner 301 at operation 102. For example, liner 301 may have a lateral width in the range of 1 to 5 nm. In some embodiments, liner 301 has a lateral width of not more than 10 nm. In some embodiments, liner 301 has a lateral width of not more than 5 nm. In some embodiments, liner 301 has a lateral width of not more than 2 nm.

As discussed, conductive features 403 are formed within liners 301. Liners 301 may be on insulator material 204 or liners 301 may be formed on another material such as an additional liner formed on insulator material 204. In some embodiments, a liner of TiN or TiN and W is first deposited, followed by a nucleation layer such as liner 301, which is followed by deposition of bulk W to fill the via/trench.

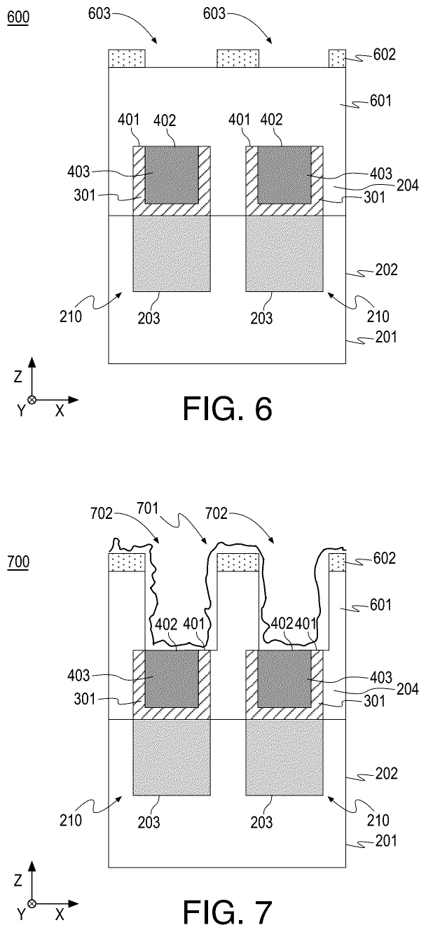

FIG. 5 illustrates a cross-sectional side view of an integrated circuit structure 500 similar to integrated circuit structure 400 with liners 301 being formed on additional liners 501. For example, liners 501 may be titanium nitride barrier layers (e.g., including titanium and nitrogen) that provide for advantages including adhesion, prevention of migration of conductive elements, and others. In some embodiments, liners 501 include titanium and nitrogen. In some embodiments, liners 501 include titanium, nitrogen, and tungsten. Liners 501 may be formed prior to operation 102 as a conformal film and then planarized at operation 103, for example. In such contexts liner 301 may have any characteristics discussed elsewhere herein. Exemplary embodiments illustrated with respect to FIGS. 6-11 continue with the example of FIG. 4 for the sake of clarity of presentation.

Returning to FIG. 1, processing continues at operation 104, where an insulator layer is deposited over the conductive feature and liner and a pattern is formed on the insulator layer. The insulator layer may be any suitable insulating or dielectric material such as one or more of silicon oxide, silicon nitride, silicon oxynitride, silicon carbide, and so on. The insulator layer may be deposited to any suitable thickness using any suitable technique or techniques such as thermal or plasma-enhanced chemical vapor deposition. A patterned layer is then formed on the insulator layer such that conductors, for example, are to be formed in openings of the pattern. In some embodiments, the patterned layer is a hardmask layer such as a patterned titanium nitride hardmask, although other materials may be used. In some embodiments, a bulk hardmask layer is formed and then the pattern is transferred to the bulk hardmask layer using lithography techniques, followed by ashing of the resist layer used in the lithography operation.

FIG. 6 illustrates a cross-sectional side view of an integrated circuit structure 600 similar to integrated circuit structure 400 after the formation of insulator material 601 and patterned hardmask layer 602. As shown, insulator material 601 (e.g., an insulator layer having a substantially planar top surface) covers conductive features 403 liners 301. Insulator material 601 is illustrated as continuous with insulator material 204 for the sake of clarity of presentation. Patterned hardmask layer 602 is formed over insulator material 601 (which may be planarized) such that openings 603 of patterned hardmask layer 602 provide a pattern where additional conductive features such as metal lines, metal vias, etc. are to be formed in contact with conductive features 403 and liners 301. Although discussed with respect to conductive features contacting conductive features 403 liners 301 any suitable component or feature such as a semiconductor material or a capacitor dielectric or the like may contact conductive features 403 liners 301. For example, integrated circuit structure 600 illustrates a structure after metal hardmask patterning.

Returning to FIG. 1, processing continues at operation 105, where openings are etched in the insulator layer using the discussed patterned hardmask layer. The openings in the insulator layer are etched using dry etch techniques that expose top surfaces of the conductive features and liners but leave undesirable artifacts of dry etch polymer and/or residue.

FIG. 7 illustrates a cross-sectional side view of an integrated circuit structure 700 similar to integrated circuit structure 600 after etching to form openings 702 in insulator material 601 while leaving undesirable polymer/residue 701. As shown, polymer/residue 701 is on sidewalls of insulator material 601 defined by openings 702, top surfaces 402 of conductive features 403 and exposed top surfaces 401 of liners 301. Polymer/residue 701 may include any materials post dry etch (e.g., plasma etch) such as portions of insulator material 601 or dry etch chemicals or the like. For example, integrated circuit structure 700 illustrates a structure after etch, such that the etch may be characterized as a trench etch (e.g., to form trench conductors) or a via etch (e.g., to form via conductors). As will be appreciated, prior to contacting conductive features 403 and liners 301, it is desirable to remove polymer/residue 701. As shown, at least a portion of top surface 402 of conductive feature 403 and at least a portion of top surface 401 of liner 301 are exposed. As discussed, conductive feature 403 is within liner 301 and conductive feature 403 is adjacent to IC device 210, such that conductive feature 403 is substantially pure tungsten or pure tungsten and liner 301 includes tungsten and boron. As discussed, portions of insulator material 601 (or an insulator layer) may be dry etched to expose at least portions of conductive feature 403 and liner 301.

During such plasma etch processing, oxygen and other components such as carbon and/or nitrogen may be added at the exposed top surfaces of liners 301. For example, at top surface 401 of liner 301, a portion of liner 301 may include boron and tungsten (as discussed above) as well as oxygen. Details of the portion of liner 301 at top surface 401 after treatment for galvanic corrosion prevention are discussed herein below.

Returning to FIG. 1, processing continues at operation 106, where the exposed top surface of the liner is treated with a hydrogen/nitrogen (H₂/N₂) plasma to modify a portion of the liner extending from the top surface. That is, the modified portion is at the top surface and extending downwardly into the liner. As discussed, the hydrogen/nitrogen plasma treatment modifies the top portion of the liner such that galvanic corrosion is prevented at a subsequent wet etch process.

Notably, the galvanic corrosion of B₂H₆-based tungsten gap filled conductors (e.g., via/trench conductors) is prevented during a wet cleaning step or wet etch step that may use alkanolamine based cleaning chemistries or formulation without tungsten corrosion inhibitors. As used herein the term alkanolamine based cleaning chemistries indicates use of alkanolamines (amino alcohols), which are organic compounds containing both a hydroxyl functional group and an amino functional group. This corrosion prevention is achieved by a hydrogen/nitrogen plasma treatment before the wet cleaning step with the hydrogen/nitrogen plasma treatment modifying the top surface of the B₂H₆ based nucleation layer. In some embodiments, the hydrogen/nitrogen treatment forms WNₓ or WOₓN_{y} at the exposed top portion of the liner. Thus, both the tungsten conductive feature (e.g., gap fill metal) and the liner (e.g., nucleation liner or layer) becomes more resistive to galvanic corrosion using alkanolamine based cleaning chemistries.

Such processing provides a variety of advantages including elimination of tungsten corrosion during wet polymer/residual cleaning (particularly at the liner/bulk tungsten interface), increase in the process window of wet cleaning due to additional tungsten corrosion protection, and avoidance of corrosion inhibitors in the wet clean formulation, which eliminates particle defects that can be introduced by corrosion inhibitors, significantly reduces chemical cost of wet clean formulation, and eliminates threats to the environment due to fab chemical waste using corrosion inhibitors.

As discussed, the top surface of the liner is treated with hydrogen/nitrogen plasma to modify a portion of the liner extending from the top surface of the liner to include nitrogen. The hydrogen/nitrogen (H₂/N₂) plasma treatment may be performed using any suitable technique or techniques. In some embodiments, the hydrogen/nitrogen plasma treatment is a hydrogen/nitrogen plasma treatment with a nitrogen flow percentage between 87.5 to 90% (with a balance of hydrogen flow percentage between 10 and 12.5%), a process temperature between 250 to 300° C., a process pressure between 150 and 200 Pa, a treatment duration between 30 to 80 seconds, and operated at a source power between 1000 and 1700 W. However, other process parameters may be used.

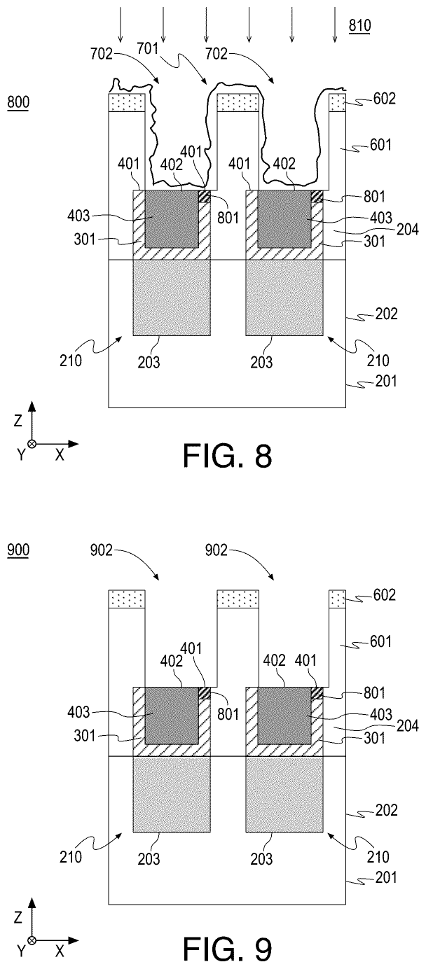

FIG. 8 illustrates a cross-sectional side view of an integrated circuit structure 800 similar to integrated circuit structure 700 after hydrogen/nitrogen (H₂/N₂) plasma treatment 810 to form modified or treated portions 801 of liners 301. As shown, exposed portions 801 of liners 301 are modified by hydrogen/nitrogen plasma treatment 810. As discussed below, exposed portions of conductive features 403 may also be modified by hydrogen/nitrogen plasma treatment 810.

As shown with respect to FIG. 8, shifted openings 702 (e.g., vias or trenches) expose at least portions of top surfaces 401 of liners 301 and top surfaces 402 of conductive features 403 polymer/residue 701, which will subsequently be cleaned using wet etch chemistries. The simultaneous exposure of both liners 301 and conductive features 403, absent modified portions 801, to a basic pH wet cleaning chemical, for example, causes galvanic corrosion, particularly at the interface between liners 301 and conductive features 403.

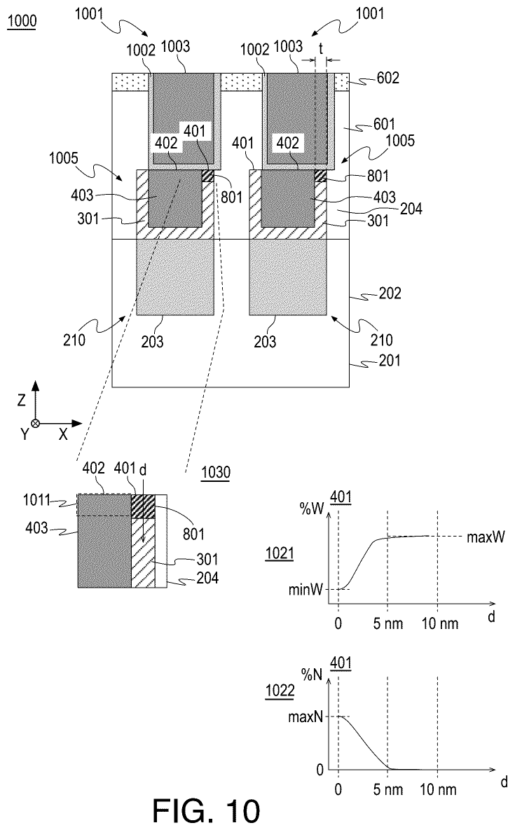

For example, before removal of polymer/residue 701, hydrogen/nitrogen plasma treatment 810 is used to modify the boron containing W top surface portion of liners 301 to tungsten nitride (e.g., including tungsten and nitrogen, WNₓ) or tungsten oxynitride (e.g., including tungsten, nitrogen, and oxygen, WOₓN_{y}), which also include boron, as shown with respect to portions 801. This modified surface or treated portion 801 (e.g., a modified tungsten nucleation layer portion including at least tungsten, boron, and nitrogen) acts as a corrosion resistive film preventing static etching of nucleation tungsten, and further eliminates galvanic corrosion at the interface between conductive features 403 (e.g., gap fill tungsten) and treated portions 801 (e.g., the tungsten-boron nucleation layer interface). For example, galvanic corrosion may be prevented due to a shift in the electro-chemical potential difference between the material of liner 301 and the bulk tungsten of conductive feature 403. Notably, after modification, the static etching rate between liners 301 and conductive features 403 using alkanolamine based wet chemistries is negligible. The compositions and characteristics of treated portion 801 are discussed further herein below with respect to FIG. 10.

Returning to FIG. 1, processing continues at operation 107, where a wet etch is performed to remove polymer/residue materials that remain due to the plasma etching performed at operation 105. As discussed, such wet etching may, absent the treatment performed at operation 106, cause undesirable galvanic corrosion. The wet etch of operation 107 may be performed using any suitable technique or techniques. In some embodiments, the wet etch includes an alkanolamine wet etch chemistry. As discussed, alkanolamine chemistries have a basic pH, which enhances tungsten corrosion due to its favorable electrochemical potential.

FIG. 9 illustrates a cross-sectional side view of an integrated circuit structure 900 similar to integrated circuit structure 800 after wet etch removal of polymer/residue 701 to provide substantially pristine openings 902. Notably, modified or treated portions 801 of liners 301 protect against galvanic corrosion during the wet etch. In some embodiments, the wet etch uses an alkanolamine chemistry.

Returning to FIG. 1, processing continues at operation 108, where conductive or metallization features are formed within the cleaned openings and on the cleaned exposed surfaces of the conductive features and the liners. The metallization conductive or metallization features may be formed using any suitable technique or techniques such as those discussed with respect to methods 100 or others. In some embodiments, the conductive or metallization features are formed of a different metal such as copper or the like.

FIG. 10 illustrates a cross-sectional side view of an integrated circuit structure 1000 similar to integrated circuit structure 900 after formation of metallization features 1001, including liners 1002 and fill metals 1003. Metallization features 1001 may be formed using deposition and planarization techniques, for example. In some embodiments, liners 1002 include the same or similar features with respect to liners 301 and fill metals 1003 include the same or similar features with respect to conductive features 403. However, other conductive metallizations may be used. For example, liners 1002 may be titanium nitride or tantalum nitride and fill metals 1003 may be copper. As shown in FIG. 10, conductive feature 403 and liner 301 may be collectively characterized as a conductor 1005.

As shown, integrated circuit structure 1000 includes conductive feature 403 adjacent to insulator material 204 and electrically coupled to IC device 210, which includes component 203. As discussed, conductive feature 403 is tungsten such as substantially pure or pure tungsten. For example, conductive feature 403 may be 99%, 99.5%, or 99.9% tungsten. Integrated circuit structure 1000 further includes liner 301 between conductive feature 403 and insulator material 204. Liner 301 includes top surface 401 adjacent conductive feature 403, such that treated portion 801 of liner 301, extending from top surface 401 into an interior of liner 301 includes tungsten, boron, and nitrogen. For example, treated portion 801 is a part or portion liner 301 including a volume defined at least in part by top surface 401 and extending in the negative z-direction (e.g., in a depth) into liner 301.

As discussed, prior to modification, treated portion 801 included at least tungsten and boron. Hydrogen/nitrogen plasma treatment 810 modifies treated portion 801 to include at least tungsten, boron, and nitrogen. Furthermore, prior plasma etch processing and/or hydrogen/nitrogen plasma treatment 810 and/or exposure to atmospheric conditions may cause treated portion 801 to include at least tungsten, boron, nitrogen, and oxygen and/or carbon. Such modification provides a corrosion resistive film such that tungsten galvanic corrosion is reduced or eliminated during operation 107. Treated portion 801 may include tungsten, boron, nitrogen, and optionally oxygen and/or carbon in any suitable compositions to provide a corrosion resistive film as discussed.

In some embodiments, treated portion 801 of liner 301 includes not less than 5% nitrogen. In some embodiments, treated portion 801 of liner 301 includes not more than 2% boron and not less than 10% nitrogen. In some embodiments, treated portion 801 of liner 301 includes not less than 20% tungsten. In some embodiments, treated portion 801 of liner 301 includes not more than 3% boron, not more than 2% boron, or not more than 1.5% boron. In some embodiments, treated portion 801 of liner 301 includes boron in the range of 0.5 to 3%, boron in the range of 1 to 2%, or boron in the range of 1 to 1.5%. In some embodiments, treated portion 801 of liner 301 includes not less than 5% nitrogen, not less than 8% nitrogen, or not more than 10% nitrogen. In some embodiments, treated portion 801 of liner 301 includes nitrogen in the range of 8 to 12%, nitrogen in the range of 10 to 12%, or nitrogen in the range of 11 to 12%. In some embodiments, treated portion 801 of liner 301 includes not less than 20% tungsten, not less than 22.5% tungsten, or not less than 24% tungsten. In some embodiments, treated portion 801 of liner 301 includes tungsten in the range of 20 to 30%, tungsten in the range of 22.5 to 27.5%, or tungsten in the range of 20 to 25%.

The remaining material of treated portion 801 of liner 301 may include carbon and/or oxygen, for example. In some embodiments, treated portion 801 of liner 301 is greater than 20% tungsten, not more than 3% boron, and not less than 5% nitrogen. In some embodiments, treated portion 801 of liner 301 is greater than 20% tungsten, not more than 2% boron, and not less than 10% nitrogen. In some embodiments, treated portion 801 of liner 301 is greater than 20% tungsten, not more than 3% boron, not less than 8% nitrogen, carbon in the range of 10 to 15%, and oxygen in the range of 45 to 55%. For example, treated portion 801 may be a tungsten nitride that includes boron or a tungsten oxynitride that includes boron.

As discussed, liner 301 has a lateral width or thickness t along top surface 401 of liner of liner such that treated portion 801 substantially the same lateral width or thickness t. In some embodiments, the lateral width of treated portion 801 is not more than 10 nm. In some embodiments, the lateral width of treated portion 801 is not more than 5 nm. In some embodiments, the lateral width of treated portion 801 is not more than 2 nm.

In addition, a concentration of the components of treated portion 801 may vary along a depth d, as shown in enlarged view 1030. As shown, depth d extends downwardly from top surface 401 of liner 301 liner and orthogonal to the discussed lateral width (e.g., depth d extends in the negative z-direction while the lateral width is in the x-y plane). For example, depth d may be zero at top surface 401 and may increase along the negative z-direction. Notably, the concentration of the components of treated portion 801 varies along depth d with increasing tungsten concentration along depth d, decreasing nitrogen concentration along depth d, decreasing oxygen concentration along depth d (if evident), and decreasing carbon concentration along depth d (if evident). Furthermore, at a particular depth d, the composition of liner 301 becomes substantially constant and substantially matches that of the material deposited at operation 102.

An exemplary tungsten versus depth chart 1021 is shown in FIG. 10, where depth d is zero at top surface 401 and increases along the negative z-direction. As shown, at top surface 401, the tungsten concentration is at a minimum value minW, which may be in the range of about 25% to 30% in some embodiments. Along depth d, the tungsten concentration in treated portion 801 increases such that tungsten concentration versus depth is a monotonically increasing function. At a particular depth, (e.g., about 5 nm), the tungsten concentration is within 5% of its maximum value maxW, and at a greater depth (e.g., about 10 nm), the tungsten concentration is at its maximum value maxW. Although illustrated with respect to depths of 5 nm and 10 nm, other depths may be observed.

Similarly, an exemplary nitrogen versus depth chart 1022 is shown in FIG. 10. If evident in the material composition, an oxygen versus depth and/or a carbon versus depth chart may be substantially the same as that of nitrogen versus depth chart 1022, and those charts are not repeated for the sake of brevity. As shown, at top surface 401, the nitrogen concentration is at a maximum value maxN, which may be in the range of about 7.5% to 12.5% in some embodiments. Along depth d, the nitrogen concentration in treated portion 801 decreases such that nitrogen concentration versus depth is a monotonically decreasing function. At a particular depth (e.g., about 5 nm), the nitrogen concentration is negligible such as about 0.1%, and at a greater depth (e.g., about 8 to 10 nm), nitrogen is absent. Although illustrated with respect to depths of 5 nm and 8-10 nm, other depths may be observed.

For example, beginning at top surface 401 of treated portion 801, scanning along depth d from top surface 401 in the negative z-direction, tungsten (W), nitrogen (N), oxygen (O), and boron (B) may be present (overlapping) at top surface 401 of treated portion 801 of liner 301. In some embodiments, tungsten (W), nitrogen (N), and boron (B) are present. In some embodiments, treated portion 801 of liner 301 includes a mixed phase of WNₓO_{y}/WN_{y} and B. In some embodiments, tungsten (W), nitrogen (N), oxygen (O), carbon (C), and boron (B). In some embodiments, tungsten (W), nitrogen (N), carbon (C), and boron (B).

As discussed, the treatment of treated portion 801 reduces or eliminated galvanic corrosion is subsequent wet etch processing. As shown with respect to treated portion 1011 of conductive feature 403 in enlarged view 1030, treated portion 1011 of conductive feature 403 may also be modified by hydrogen/nitrogen plasma treatment 810. For example, treated portion 1011 may include a tungsten nitride or tungsten oxynitride material (absent boron) in analogy to that of treated portion 801. In some embodiments, treated portion 1011 of conductive feature 403, which extends from top surface 402 of conductive feature 403 includes tungsten and nitrogen, such that treated portion 1011 of conductive feature 403 is absent boron. However, it is noted that the corrosion benefits discussed herein is largely due to the modification of treated portion 801 because of liner 301 (e.g., nucleation layer) having a different corrosion potential relative to conductive feature 403.

Returning to FIG. 1, processing continues at operation 109, where front end processing, such as formation frontside metallization layers, and continued processing is performed as is known in the art. Such processing may include backside power delivery processing, dicing, packaging, assembly, and so on. The resultant device (e.g., integrated circuit die) may then be implemented in any suitable form factor device such as a laptop, a netbook, a notebook, an ultrabook, a smartphone, a tablet, a personal digital assistant, an ultra-mobile PC, a mobile phone, a desktop computer, a server, a printer, a scanner, a monitor, a set-top box, an entertainment control unit, a digital camera, a portable music player, a digital video recorder, or the like.

FIG. 11 illustrates a cross-sectional side view of an integrated circuit structure 1100 incorporating conductors 1005 into a transistor device 1131. For example, with reference to FIG. 10, any or each of conductors 1005 may include conductive feature 403 and liner 301 as discussed herein. As shown, transistor device 1131 includes semiconductor structures 1123 extending between a source structure 1121 and drain structure 1122. Each of semiconductor structures 1123 includes a channel region contacted by and controlled by gate structure 1125, which include a gate dielectric 1126 and a gate electrode 1127. As shown in FIG. 11, conductors 1005 may contact a source (e.g., source structure 1121), a drain (e.g., drain structure 1122), or a gate portion (e.g., gate electrode 1127 or gate dielectric 1126 if conductor 1005 is the gate electrode) of a transistor (e.g., transistor device 1131).

FIG. 11 further illustrates frontside metallization layers 1101 (or frontside interconnect layers). Frontside metallization layers 1101 may be formed using any suitable technique or techniques such as dual damascene techniques, single damascene techniques, subtractive metallization patterning techniques, or the like. For example, interconnectivity, signal routing, power-delivery, and the like may be provided by frontside metallization layers 1101. As used herein, the term metallization layer indicates metal interconnections or wires that provide electrical routing. In some embodiments, conductors 1005 are part of frontside metallization layers 1101. In some embodiments, metallization features 1001 are part of frontside metallization layers 1101. Adjacent metallization layers, such as metallization interconnects 1102, are interconnected by vias, such as vias 1103, that may be characterized as part of the metallization layers or between the metallization layers. As shown, in some embodiments, frontside metallization layers 1101 are formed over and immediately adjacent transistor device 1131. In the illustrated example, frontside metallization layers 1101 include M0, V0, M1, M2/V1, M3/V2, and M4/V3. However, frontside metallization layers 1101 may include any number of metallization layers such as six, eight, or more metallization layers. In some embodiments, an integrated circuit structure 1100 is implemented as part of an integrated circuit (IC) die 1130.

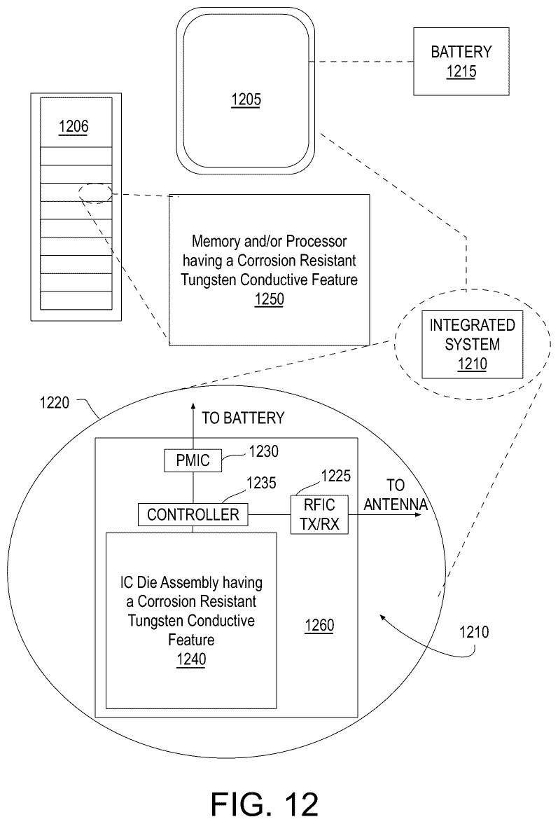

FIG. 12 illustrates exemplary systems employing integrated circuit structures having a tungsten conductive feature in a corrosion resistant liner, in accordance with some embodiments. The system may be a mobile computing platform 1205 and/or a data server machine 1206, for example. Either may employ a monolithic IC die, for example, having a tungsten conductive feature in a corrosion resistant liner as described elsewhere herein. Server machine 1206 may be any commercial server, for example including any number of high-performance computing platforms disposed within a rack and networked together for electronic data processing, which in the exemplary embodiment includes an IC die assembly 1250 with a field effect transistor and a tungsten conductive feature in a corrosion resistant liner as described elsewhere herein. Mobile computing platform 1205 may be any portable device configured for each of electronic data display, electronic data processing, wireless electronic data transmission, or the like. For example, mobile computing platform 1205 may be any of a tablet, a smart phone, a laptop computer, etc., and may include a display screen (e.g., a capacitive, inductive, resistive, or optical touchscreen), a chip-level or package-level integrated system 1210, and a battery/power supply 1215. Although illustrated with respect to mobile computing platform 1205, in other examples, chip-level or package-level integrated system 1210 and a battery/power supply 1215 may be implemented in a desktop computing platform, an automotive computing platform, an internet of things platform, or the like. As discussed below, in some examples, the disclosed systems may include a sub-system 1260 such as a system on a chip (SOC) or an integrated system of multiple ICs, which is illustrated with respect to mobile computing platform 1205.

Whether disposed within integrated system 1210 illustrated in expanded view 1220 or as a stand-alone packaged device within data server machine 1206, sub-system 1260 may include memory circuitry and/or processor circuitry 1240 (e.g., RAM, a microprocessor, a multi-core microprocessor, graphics processor, etc.), a power management integrated circuit (PMIC) 1230, a controller 1235, and a radio frequency integrated circuit (RFIC) 1225 (e.g., including a wideband RF transmitter and/or receiver (TX/RX)). As shown, one or more IC dice, such as memory circuitry and/or processor circuitry 1240 may be assembled and implemented such that one or more have a tungsten conductive feature in a corrosion resistant liner as described herein. In some embodiments, RFIC 1225 includes a digital baseband and an analog front end module further comprising a power amplifier on a transmit path and a low noise amplifier on a receive path). Functionally, PMIC 1230 may perform battery power regulation, DC-to-DC conversion, etc., and so has an input coupled to battery/power supply 1215, and an output providing a current supply to other functional modules. As further illustrated in FIG. 12, in the exemplary embodiment, RFIC 1225 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Memory circuitry and/or processor circuitry 1240 may provide memory functionality for sub-system 1260, high level control, data processing and the like for sub-system 1260. In alternative implementations, each of the SOC modules may be integrated onto separate ICs coupled to a package substrate, interposer, or board.

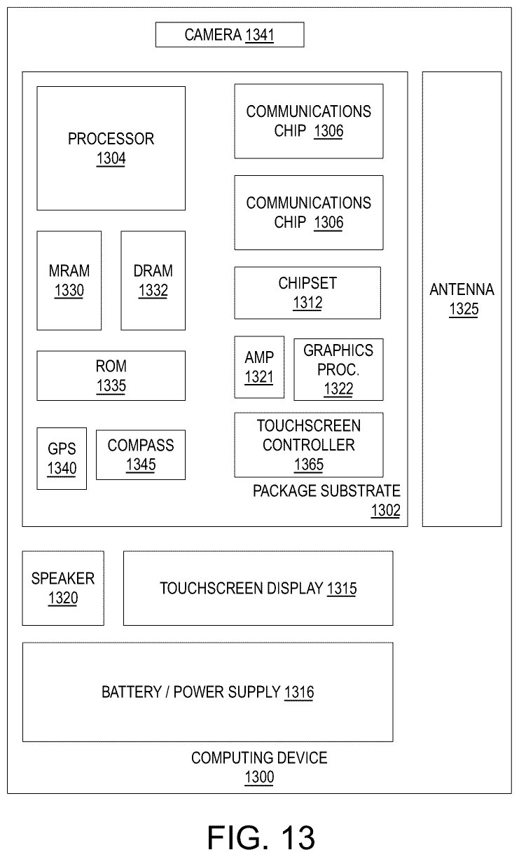

FIG. 13 is a functional block diagram of an electronic computing device 1300, in accordance with some embodiments. For example, device 1300 may, via any suitable component therein, implement a tungsten conductive feature in a corrosion resistant liner as discussed herein. For example, one or more IC dies of electronic computing device 1300 may deploy a transistor and a tungsten conductive feature in a corrosion resistant liner as discussed herein. Device 1300 further includes a motherboard or package substrate 1302 hosting a number of components, such as, but not limited to, a processor 1304 (e.g., an applications processor). Processor 1304 may be physically and/or electrically coupled to package substrate 1302. In some examples, processor 1304 is within an IC assembly. In general, the term “processor” or “microprocessor” may refer to any device or portion of a device that processes electronic data from registers and/or memory to transform that electronic data into other electronic data that may be further stored in registers and/or memory.

In various examples, one or more communication chips 1306 may also be physically and/or electrically coupled to the package substrate 1302. In further implementations, communication chips 1306 may be part of processor 1304. Depending on its applications, computing device 1300 may include other components that may or may not be physically and electrically coupled to package substrate 1302. These other components include, but are not limited to, volatile memory (e.g., DRAM 1332), non-volatile memory (e.g., ROM 1335), flash memory (e.g., NAND or NOR), magnetic memory (MRAM 1330), a graphics processor 1322, a digital signal processor, a crypto processor, a chipset 1312, an antenna 1325, touchscreen display 1315, touchscreen controller 1365, battery/power supply 1316, audio codec, video codec, power amplifier 1321, global positioning system (GPS) device 1340, compass 1345, accelerometer, gyroscope, speaker 1320, camera 1341, and mass storage device (such as hard disk drive, solid-state drive (SSD), compact disk (CD), digital versatile disk (DVD), and so forth, or the like.

Communication chips 1306 may enable wireless communications for the transfer of data to and from the computing device 1300. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chips 1306 may implement any of a number of wireless standards or protocols, including, but not limited to, those described elsewhere herein. As discussed, computing device 1300 may include a plurality of communication chips 1306. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others. Battery/power supply 1316 may include any suitable power supply circuitry and, optionally, a battery source to provide power to components of electronic computing device 1300.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described but can be practiced with modification and alteration without departing from the scope of the appended claims. For example, the above embodiments may include specific combinations of features as further provided below.

The following pertains to exemplary embodiments.

In one or more first embodiments, an apparatus comprises a metal structure adjacent to an insulator material and electrically coupled to an integrated circuit device, the metal structure comprising substantially pure tungsten, and a liner between the metal structure and the insulator material, the liner comprising a top surface adjacent the metal structure, such that a portion of the liner extending from the top surface of the liner comprises tungsten, boron, and not less than 5% nitrogen.

In one or more second embodiments, further to the first embodiments, the portion of the liner comprises not more than 3% boron and not less than 10% nitrogen.

In one or more third embodiments, further to the first or second embodiments, the portion of the liner further comprises oxygen.

In one or more fourth embodiments, further to the first through third embodiments, the portion of the liner comprises not less than 20% tungsten.

In one or more fifth embodiments, further to the first through fourth embodiments, the liner has a lateral width along the top surface of the liner of not more than 10 nm, such that a concentration of tungsten in the portion of the liner increases along a depth of the liner extending downwardly from the top surface of the liner and orthogonal to the lateral width.

In one or more sixth embodiments, further to the first through fifth embodiments, a concentration of nitrogen in the portion of the liner decreases extending along the depth.

In one or more seventh embodiments, further to the first through sixth embodiments, a concentration of tungsten in the portion of the liner increases extending along the depth.

In one or more eighth embodiments, further to the first through seventh embodiments, a portion of the metal structure extending from the top surface of the metal structure comprises tungsten and nitrogen, wherein the portion of the metal structure is absent boron.

In one or more ninth embodiments, further to the first through eighth embodiments, the apparatus further comprises a second liner between the liner and the insulator material, the second liner comprising titanium and nitrogen.

In one or more tenth embodiments, further to the first through ninth embodiments, the metal structure is electrically coupled to a component of the integrated circuit device, the component of the integrated circuit device comprising one of a source, a drain, or a gate portion of a transistor.

In one or more eleventh embodiments, a system comprises an IC die having an apparatus according to any of the first through twelfth embodiments, the system further including a power supply and/or a display coupled to the IC die.

In one or more twelfth embodiments, a system comprises an IC die comprising a transistor, a metal structure adjacent to an insulator material and electrically coupled to the transistor, the metal structure comprising substantially pure tungsten, and a liner between the metal structure and the insulator material, the liner comprising a top surface adjacent a top surface of the metal structure, such that a portion of the liner extending from the top surface of the liner comprises tungsten, boron, not less than 5% nitrogen, and oxygen, and a power supply and/or a display coupled to the IC die.

In one or more thirteenth embodiments, further to the twelfth embodiments, the portion of the liner comprises not more than 3% boron and not less than 10% nitrogen.

In one or more fourteenth embodiments, further to the twelfth or thirteenth embodiments, the portion of the liner comprises not less than 20% tungsten.

In one or more fifteenth embodiments, further to the twelfth through fourteenth embodiments, the liner has a lateral width along the top surface of the liner of not more than 10 nm, such that a concentration of tungsten in the portion of the liner increases along a depth of the liner extending downwardly from the top surface of the liner and orthogonal to the lateral width, and a concentration of nitrogen in the portion of the liner decreases extending along the depth.

In one or more sixteenth embodiments, further to the twelfth through fifteenth embodiments, the IC die further comprises a second liner between the liner and the insulator material, the second liner comprising titanium and nitrogen, and wherein the metal structure is electrically coupled to one of a source, a drain, or a gate portion of the transistor.

In one or more seventeenth embodiments, a method comprises exposing a top surface of a metal structure and a top surface of a liner, the metal structure within the liner and the metal structure adjacent to an integrated circuit device, such that the metal structure comprises substantially pure tungsten and the liner comprises tungsten and boron, treating the top surface of the liner with a nitrogen plasma to modify a portion of the liner extending from the top surface of the liner to include nitrogen, and performing, subsequent to said treating the top surface of the liner, a wet etch on the top surface of the metal structure and the top surface of the liner.

In one or more eighteenth embodiments, further to the seventeenth embodiments, the portion of the liner comprises not more than 3% boron, such that, subsequent to said treating the top surface of the liner, a modified portion of the liner comprises not less than 5% nitrogen.

In one or more nineteenth embodiments, further to the seventeenth or eighteenth embodiments, said treating the top surface of the liner with a nitrogen plasma comprises hydrogen/nitrogen plasma treatment with a nitrogen flow percentage between 87.5 to 90%, a process temperature between 250 to 300° C., and a treatment duration between 30 to 80 seconds.

In one or more twentieth embodiments, further to the seventeenth through nineteenth embodiments, the wet etch comprises an alkanolamine wet etch chemistry.

In one or more twenty-first embodiments, further to the seventeenth through twentieth embodiments, the method further comprises forming the liner via nucleation layer deposition using a boron/hydrogen reaction with tungsten hexafluoride, forming the metal structure using bulk tungsten deposition, depositing an insulator layer over the metal structure and the liner, and dry etching a portion of the insulator layer to expose portions of the metal structure and the liner.

It will be recognized that the invention is not limited to the embodiments so described but can be practiced with modification and alteration without departing from the scope of the appended claims. For example, the above embodiments may include specific combination of features. However, the above embodiments are not limited in this regard, and, in various implementations, the above embodiments may include the undertaking only a subset of such features, undertaking a different order of such features, undertaking a different combination of such features, and/or undertaking additional features than those features explicitly listed. The scope of the invention should, therefore, be determined with reference to the appended claims, along with the full scope of equivalents to which such claims are entitled.

What is claimed is:

1. An apparatus, comprising:
a metal structure adjacent to an insulator material and electrically coupled to an integrated circuit device, the metal structure comprising substantially pure tungsten; and
a liner between the metal structure and the insulator material, the liner comprising a top surface adjacent the metal structure, wherein a portion of the liner extending from the top surface of the liner comprises tungsten, boron, and not less than 5% nitrogen.

2. The apparatus of claim 1, wherein the portion of the liner comprises not more than 3% boron and not less than 10% nitrogen.

3. The apparatus of claim 2, wherein the portion of the liner further comprises oxygen.

4. The apparatus of claim 3, wherein the portion of the liner comprises not less than 20% tungsten.

5. The apparatus of claim 1, wherein the liner has a lateral width along the top surface of the liner of not more than 10 nm, and wherein a concentration of tungsten in the portion of the liner increases along a depth of the liner extending downwardly from the top surface of the liner and orthogonal to the lateral width.

6. The apparatus of claim 5, wherein a concentration of nitrogen in the portion of the liner decreases extending along the depth.

7. The apparatus of claim 6, wherein a concentration of tungsten in the portion of the liner increases extending along the depth.

8. The apparatus of claim 1, wherein a portion of the metal structure extending from the top surface of the metal structure comprises tungsten and nitrogen, wherein the portion of the metal structure is absent boron.

9. The apparatus of claim 1, further comprising a second liner between the liner and the insulator material, the second liner comprising titanium and nitrogen.

10. The apparatus of claim 1, wherein the metal structure is electrically coupled to a component of the integrated circuit device, the component of the integrated circuit device comprising one of a source, a drain, or a gate portion of a transistor.

11. A system, comprising:
an integrated circuit (IC) die comprising:
a transistor;
a metal structure adjacent to an insulator material and electrically coupled to the transistor, the metal structure comprising substantially pure tungsten; and
a liner between the metal structure and the insulator material, the liner comprising a top surface adjacent a top surface of the metal structure, wherein a portion of the liner extending from the top surface of the liner comprises tungsten, boron, not less than 5% nitrogen, and oxygen; and
a power supply coupled to the IC die.

12. The system of claim 11, wherein the portion of the liner comprises not more than 3% boron and not less than 10% nitrogen.

13. The system of claim 12, wherein the portion of the liner comprises not less than 20% tungsten.

14. The system of claim 11, wherein the liner has a lateral width along the top surface of the liner of not more than 10 nm, and wherein a concentration of tungsten in the portion of the liner increases along a depth of the liner extending downwardly from the top surface of the liner and orthogonal to the lateral width, and a concentration of nitrogen in the portion of the liner decreases extending along the depth.

15. The system of claim 11, wherein the IC die further comprises a second liner between the liner and the insulator material, the second liner comprising titanium and nitrogen, and wherein the metal structure is electrically coupled to one of a source, a drain, or a gate portion of the transistor.

16. A method, comprising:
exposing a top surface of a metal structure and a top surface of a liner, the metal structure within the liner and the metal structure adjacent to an integrated circuit device, wherein the metal structure comprises substantially pure tungsten and the liner comprises tungsten and boron;
treating the top surface of the liner with a nitrogen plasma to modify a portion of the liner extending from the top surface of the liner to include nitrogen; and
performing, subsequent to said treating the top surface of the liner, a wet etch on the top surface of the metal structure and the top surface of the liner.

17. The method of claim 16, wherein the portion of the liner comprises not more than 3% boron, and wherein, subsequent to said treating the top surface of the liner, a modified portion of the liner comprises not less than 5% nitrogen.

18. The method of claim 16, wherein said treating the top surface of the liner with a nitrogen plasma comprises hydrogen/nitrogen plasma treatment with a nitrogen flow percentage between 87.5 to 90%, a process temperature between 250 to 300° C., and a treatment duration between 30to 80 seconds.

19. The method of claim 16, wherein the wet etch comprises an alkanolamine wet etch chemistry.

20. The method of claim 16, further comprising:
forming the liner via nucleation layer deposition using a boron/hydrogen reaction with tungsten hexafluoride;
forming the metal structure using bulk tungsten deposition;
depositing an insulator layer over the metal structure and the liner; and
dry etching a portion of the insulator layer to expose portions of the metal structure and the liner.
